(19) United States
(12) Patent Application Publication
(10) Pub. No.: US 2013/0074898 A1
(43) Pub. Date: Mar. 28, 2013

(54) THERMOELECTRIC COOLING SYSTEM UTILIZING THE THOMSON EFFECT

(71) Applicant: G. Jeffrey Snyder, Pasadena, CA (US)

(72) Inventor: G. Jeffrey Snyder, Pasadena, CA (US)

(73) Assignee: CALIFORNIA INSTITUTE OF TECHNOLOGY, Pasadena, CA (US)

(21) Appl. No.: 13/625,664

(22) Filed: Sep. 24, 2012

Related U.S. Application Data
(60) Provisional application No. 61/538,596, filed on Sep. 23, 2011.

(51) Int. Cl. H01L 35/32

(52) U.S. Cl. 136/203

(57) ABSTRACT

Thermoelectric cooling systems are disclosed that utilize the Thomson effect. The disclosed systems can be used, for example, in cryogenic applications. In one aspect, a system is provided for thermoelectric cooling. The system comprises a pair of semiconductor elements, a cold plate and a hot plate. The pair of semiconductor elements comprises a P-type semiconductor element having a first carrier concentration and an N-type semiconductor element having a second carrier concentration. The first carrier concentration is functionally graded over the P-type semiconductor element and the second carrier concentration is functionally graded over the N-type semiconductor element. Each semiconductor element has a cold end and a hot end. The cold plate is thermally coupled to the cold ends of the P-type semiconductor elements and the N-type semiconductor element. The hot plate is thermally coupled to the hot ends of the P-type semiconductor element and the N-type semiconductor element.

### CROSS-REFERENCE TO RELATED APPLICATIONS

This application claims the benefit of U.S. Provisional Application No. 61/538,596, filed Sep. 23, 2011, herein incorporated by reference in its entirety.

### STATEMENT REGARDING FEDERALLY SPONSORED RESEARCH

This invention was made with government support under Grant No. FA9550-10-1-0533 awarded by the Air Force Office of Scientific Research. The government has certain rights in the invention.

### TECHNICAL FIELD

The present disclosure relates generally to cooling systems, and more specifically, to thermoelectric cooling systems utilizing the Thomson effect.

### BACKGROUND

Peltier coolers are the most widely used solid state cooling devices, enabling a wide range of optoelectronics applications, including infrared detectors. Thermoelectric coolers have been traditionally understood by means of the Peltier effect, the thermoelectric effect which describes the reversible heat absorbed (or released) at a junction of two dissimilar materials. The traditional analysis of a Peltier cooler approximates the material properties as independent of temperature (i.e., Constant Property Model (CPM)), and results in the temperature difference for maximum cooling, ΔTₘₐₓ, being dependent on the figure of merit, ZT, of the device.

$$Δ {T}_{ma x} = \frac{{ZT}_{c}^{2}}{2} \qquad [ 1 ]$$

For the best commercial materials, this leads to a ΔTₘₐₓ of 65K, which translates to a device ZT of 0.74 at 300K. In the Constant Property Model (CPM), the device ZT is equal to the figure of merit, zT, of the material, defined as:

$$zT = \frac{{a}^{2} T}{ρ κ} \qquad [ 2 ]$$

The material zT depends on the Seebeck coefficient (α), temperature (T), electrical resistivity (ρ), and thermal conductivity (κ). In the CPM, the only way to increase ΔTₘₐₓ for a single stage is to increase zT, leading to the focus of much thermoelectric research on improving the material zT.

Even further cooling to lower temperatures can be achieved using multi-stage Peltier coolers. In principle, each stage can produce additional cooling to lower temperatures, regardless of the zT of the thermoelectric material in the stage. In practice, the thermal losses and complications of fabrication limit the performance of such devices. For example, one commercially provided 6-stage cooler provides a ΔTₘₐₓ of 127, which translates to a device ZT of 2.5 at 300K, even though similar thermoelectric materials are used as in the one stage device with zT<1. This illustrates a dramatic improvement of thermoelectric performance by staging (i.e., from device ZT of 0.7 to 2.5).

### SUMMARY

The following summary of the invention is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

In summary, the present disclosure relates generally to cooling systems, and more specifically, to thermoelectric cooling systems utilizing the Thomson effect (“Thomson coolers”). The disclosed systems can be used, for example, in cryogenic applications.

In one aspect, a system is provided for thermoelectric cooling. The system comprises a pair of semiconductor elements, a cold plate and a hot plate. The pair of semiconductor elements comprises a P-type semiconductor element having a first carrier concentration and an N-type semiconductor element having a second carrier concentration. The first carrier concentration is functionally graded over the P-type semiconductor element and the second carrier concentration is functionally graded over the N-type semiconductor element.

Each semiconductor element has a cold end and a hot end. The cold plate is thermally coupled to the cold ends of the P-type semiconductor elements and the N-type semiconductor element. The hot plate is thermally coupled to the hot ends of the P-type semiconductor element and the N-type semiconductor element.

As described herein, the most efficient thermoelectric cooler utilizes primarily the Thomson effect, rather than the Peltier effect. Such a device, herein also referred to as a “Thomson cooler”, greatly outperforms traditional Peltier coolers in cryogenic applications. While the minimum temperature achieved by a traditional Peltier cooler is limited by the figure of merit of the material, zT, a Thomson cooler could, in principle, achieve arbitrarily low temperatures, e.g., 10 K or lower, without parasitic losses. In one embodiment of the invention, the Thomson cooler can achieve a cold side temperature of 140 K or lower with a device figure of merit ZT of 5, twice that of a state-of-the art Peltier device. The manufacturing process of the Thomson cooler can be compatible with industry standards for producing infrared focal plane arrays, facilitating mass production.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1A is a graph of the reduced efficiency for a traditional constant property model (CPM) Peltier cooler.

FIG. 1B is a graph comparing the reduced efficiency of a Peltier (CPM) cooler and a cooler utilizing the optimized compatibility factor according to an embodiment of the invention.

FIG. 1C is a graph comparing the coefficient of performance (COP) of a Peltier (CPM) cooler and a cooler utilizing the optimized compatibility factor according to an embodiment of the invention.

FIG. 2 is a graph illustrating the changing Seebeck coefficient across a thermoelectric leg according to an embodiment of the invention.

FIG. 3 is a cross-sectional view of a system for thermoelectric cooling according to an embodiment of the invention.

FIG. 4 is a cross-sectional view of a system for thermoelectric cooling according to another embodiment of the invention.

FIG. 5 is a scanning Seebeck micrograph of Bi₂Te₃ with varying Seebeck coefficient, prepared via powder processing according to an embodiment of the invention.

FIG. 6 is a graph illustrating the concentration of Sb in PbTe due to directional solidification according to an embodiment of the invention.

FIG. 7A illustrates the coherent precipitates of Sb₂Te₃ in single crystal PbTe formed by directional solidification according to an embodiment of the invention.

FIG. 7B is a three-dimensional reconstruction of the oriented inclusions of FIG. 7A according to an embodiment of the invention.

FIG. 8A is a graph illustrating the decaying dopant concentration away from the surface due to diffusion doping according to an embodiment of the invention.

FIG. 8B is a graph illustrating a micrometer scale compositional gradient produced by diffusion doping according to an embodiment of the invention.

FIG. 9 illustrates two exemplary materials segmented together with metal interconnect by powder processing and diffusion bonding according to an embodiment of the invention.

### DETAILED DESCRIPTION

Systems for thermoelectric cooling utilizing the Thomson effect are described. In the following description, for purposes of explanation, numerous specific details are set forth in order to provide a thorough understanding of the exemplary embodiments. It is apparent to one skilled in the art, however, that embodiments of the invention can be practiced without these specific details or with an equivalent arrangement.

According to embodiments of the invention, the thermoelectric compatibility factor (s) is matched to the reduced current density (u); thus, the performance of a functionally graded single thermoelectric device can achieve that expected from a staged device with an infinite number of stages, without the associated losses from the interfaces. For a thermoelectric cooler, the reduced current density and the thermoelectric compatibility factor are given by:

$$\begin{matrix}u = \frac{j}{- ( κ \frac{d T}{d x} )} & [ 3 ] \\ {s}_{c} = \frac{- \sqrt{1 + zT} - 1}{α T} & [ 4 ]\end{matrix}$$

The thermoelectric compatibility factor (s) is essential in achieving the optimum efficiency determined by zT. Optimizing the self-compatibility of the device leads to arbitrarily low cooling. An optimized thermoelectric cooler has the reduced current density (u) equal to the local material compatibility factor (s). If u does not equal s, the cooling efficiency will be less than predicted by the material zT.

The ideal thermoelectric cooler maximizes coefficient of performance (COP), which relates the heat extraction to the power consumption:

$$COP = \frac{Heat Extracted}{Power In} \qquad [ 5 ]$$

The COP of a thermoelectric cooler is maximized by adjusting the electrical current. The maximum COP of a thermoelectric cooler decreases as the temperature difference between the hot and cold sides increases. As the COP approaches zero, no heat is extracted from the cold side and the maximum temperature difference, ΔTₘₐₓ, is reached.

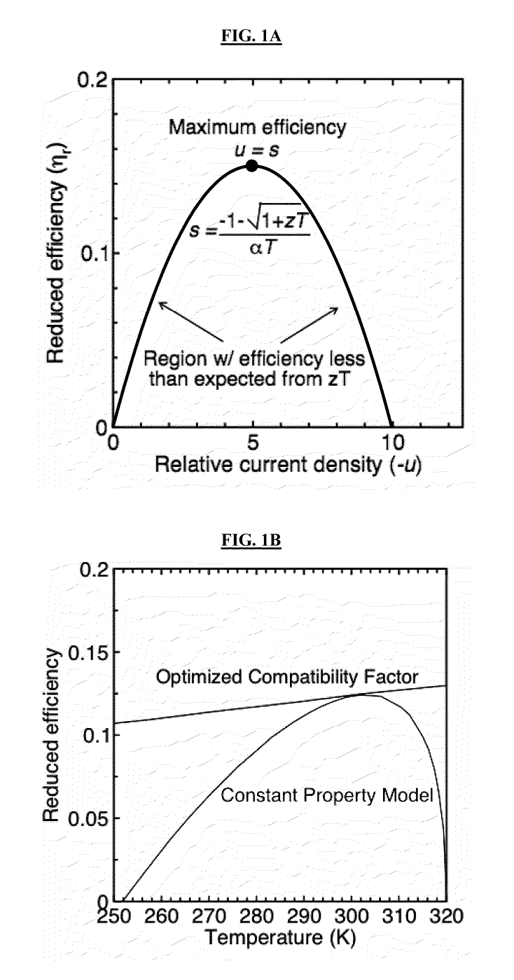

As shown in FIG. 1A, in a traditional constant property model (CPM) Peltier cooler, u=s at only one point along the leg. Because compatibility is maintained at only one point in the CPM cooler, the actual reduced efficiency or coefficient of performance (COP) is less than the optimal reduced efficiency. Thus, the overall device efficiency is significantly compromised, as shown in FIG. 1B. Thus, the CPM cooler is operating inefficiently (even negative efficiency below minimum temperature) at both the hot and cold end, requiring the need for staging.

On the other hand, a fully self-compatible cooler achieves full COP throughout the device, and therefore better cooling. In other words, the COP is maximized at every point of the cooler element, thereby enhancing device performance. As shown in FIG. 1C, the coefficient of performance (COP) of a CPM cooler crosses zero at a finite temperature, setting ΔTₘₐₓ, while the self-compatible cooler COP remains positive for all temperatures. Self-compatibility is achieved in embodiments of the invention by functionally grading: changing the carrier concentration of the material, or the material itself, gradually from the cold end to the hot end to maximize zT, while maintaining thermoelectric self-compatibility.

The COP for an optimized, self-compatible (u=s) element can be evaluated by the following equations, where ηᵣ is the reduced efficiency. The reduced efficiency can be defined for any point in the cooler, and the overall efficiency (COP) can be calculated from this local efficiency.

$$\begin{matrix}\frac{1}{COP} = exp ( {\int }_{{T}_{c}}^{{T}_{h}} \frac{1}{T} \frac{1}{{η}_{r} d T} ) - 1 & [ 6 ] \\ {η}_{r} = \frac{u ( α - u ρ κ )}{u α + \frac{1}{T}} & [ 7 ]\end{matrix}$$

The COP is largest when the reduced efficiency is maximized. The local reduced efficiency is defined by:

$${η}_{r , ma x} = \frac{\sqrt{1 + zT} - 1}{\sqrt{1 + zT} + 1} \qquad [ 8 ]$$

The local reduced efficiency is maximum when u=s, where s is the thermoelectric compatibility factor (for cooling), as defined by Equation 4. The relative current density, u, as defined by Equation 3, is adjusted by tuning the electrical current density (j) relative to the temperature gradient (∇T).

In a functionally graded thermoelectric device, the α(T), ρ(T) and κ(T) are adjusted by changing the material or doping of the material. Typically, these are adjusted to maximum zT. While large zT results in a high upper limit for efficiency, it does not actually ensure that this efficiency is achieved. To ensure this maximum efficiency, a further adjustment of α(T), ρ(T) and κ(T) are required that gives u=s.

Assuming a cooler element with no contact resistance, no thermal losses, and one-dimensional heat flux and current flow (as is assumed in CPM), Equation 9 for such an element energy balance for an infinitesimal segment can be derived. Equation 9 relates the change in heat flow (κ∇T) across a segment of thickness dx to the Joule heating (ρj²) occurring within the material, and the Thomson effect (Tj∇α). The temperature gradient will induce a heat flux (κ∇T) across this segment, limited by the thermal conductivity K according to Fourier's law. The divergence of this heat is the conservation law of energy equal to the source terms for heat. Joule heating will occur internally in this infinitesimal segment, with a magnitude dependent on the current density (j) and the electrical resistivity (ρ). The reversible Thomson heat (Tj∇α) can act as a source or a sink.

∇(−κ∇T)=ρj²−Tj∇α [9]

In the CPM model typically used to analyze Peltier coolers, the Thomson effect (Tj∇α) is zero, because the Seebeck coefficient is constant across the leg (∇α=0).

Together, Equations 3, 4 and 9 are under-constrained, as there are three independent materials properties: Seebeck coefficient (α), thermal conductivity (κ), and resistivity (ρ), all of which are a function of T, which can be freely defined at each position x along the thermoelectric leg. With the addition of two further material constraints (e.g., constant z and constant K_{lattice}) and boundary values, the graded material properties which maximize COP can be established. Evaluating Equations 6 and 7 for the case of an optimally graded material with constant z, Equations 10 and 11 are obtained. Considering the case of T_{c} approaching zero, the COP remains finite and positive, as shown in FIG. 1C.

$$\begin{matrix}\frac{1}{COP} = ( \frac{{A}_{h} - 1}{{A}_{c} - 1} ) exp ( \frac{2 ( {A}_{h} - {A}_{c} )}{( {A}_{h} - 1 ) ( {A}_{c} - 1 )} ) - 1 & [ 10 ] \\ {A}_{x} = \sqrt{1 + {zT}_{x}} & [ 11 ]\end{matrix}$$

Such a solution is fundamentally distinct from the CPM solution, where the required zT goes to infinity as the cold side temperature approaches zero. The self-compatibility (u=s) optimization method results in arbitrarily low cold side temperature for zT proportional to any finite power of T. Thus, like any CPM Peltier cooler which can, in principle, achieve a lower cold side temperature by adding an additional stage, a fully self-compatible Thomson effect cooler achieves lower cold side temperature as long as the additional material has finite zT and is compatible with the adjacent section.

In a fully self-compatible (u=s) thermoelectric cooler, the dominant thermoelectric effect is the Thomson effect, rather than the Peltier effect. The Peltier effect, Seebeck effect and Thomson effect are all manifestations of the same thermoelectric property characterized by the Seebeck coefficient. The Thomson effect describes the heat absorbed when current flows in the direction of a temperature gradient. The Thomson coefficient (τ) is related to the temperature derivative of the Seebeck coefficient via the Kelvin relations, as shown below:

$$\begin{matrix}Q = τ I \frac{d T}{d X} & [ 12 ] \\ τ = T \frac{d α}{d T} & [ 13 ]\end{matrix}$$

A good thermoelectric cooler, as described herein, thus has a rapidly changing Seebeck coefficient across the temperature gradient present in the thermoelectric leg (i.e., the P- or N-type semiconductor element), leading to a large Thomson coefficient. In contrast, in the traditional constant property model for a Peltier cooler, the Thomson coefficient is, by definition, zero. Thus, the importance of the Thomson effect for thermoelectric cooling has been previously overlooked.

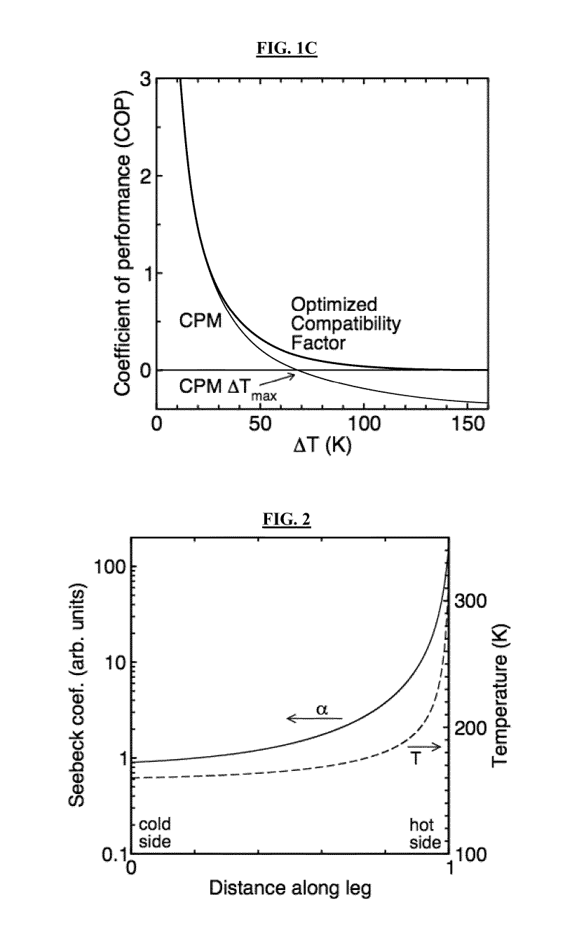

To achieve cooling to 140 K or lower with an optimized Thomson cooler, the Seebeck coefficient will vary by two or more orders of magnitude in some embodiments, as shown in FIG. 2. Such a Thomson cooler has key advantages over state-of-the-art Peltier coolers. For a given material zT, performance (ΔTₘₐₓ and COP) of the cooler is optimized. In an ideal Thomson cooler with no losses, the temperature minimum is not limited as in a traditional Peltier cooler. This leads to arbitrarily low cooling (e.g., T approaching 0 K).

High zT alone will not achieve cryogenic temperatures. Barring materials with zT greater than 10, staged devices or functionally graded materials which achieve self-compatibility must be used to achieve cryogenic cooling.

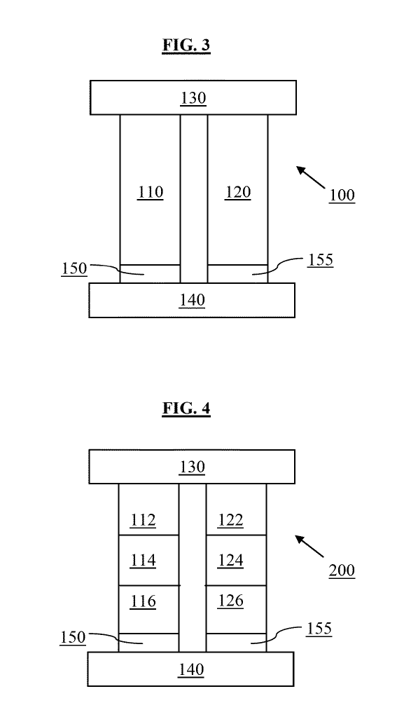

FIG. 3 is a cross-sectional view of system 100 for thermoelectric cooling according to an embodiment of the invention. System 100 comprises a pair of semiconductor elements 110, 120 sandwiched between a cold plate 130 and a hot plate 140. As described herein, “semiconductor elements” may also be referred to as “thermoelectric legs”. Semiconductor element 110 may be, for example, a P-type semiconductor element, and semiconductor element 120 may be, for example, an N-type semiconductor element. In another example, semiconductor element 110 may be an N-type semiconductor element, and semiconductor element 120 may be a P-type semiconductor element. Although shown and described as a single pair of semiconductor elements 110, 120, it is contemplated that two or more pairs of semiconductor elements may be implemented in system 100.

Semiconductor elements 110, 120 have rapidly changing Seebeck coefficients from the hot end (i.e., the end proximate to the hot plate 140) to the cold end (i.e., the end proximate to the cold plate 130). In one embodiment, the Seebeck coefficient increases by orders of magnitudes from the cold end to the hot end. In this embodiment, this variation in Seebeck coefficient in achieved in a single functionally graded material through variation in carrier concentration and temperature.

Thin film 150 is positioned between semiconductor element 110 and hot plate 140. Thin film 155 is positioned between semiconductor element 120 and hot plate 140. Thin films 150, 155 have the highest Seebeck coefficient with respect to semiconductor elements 110, 120. In this embodiment, low electrical contact resistance exists between semiconductor element 110 and thin film 150, and between semiconductor element 120 and thin film 155. This can be achieved by thin film methods on active bulk substrates.

Thin films 150, 155 may comprise, for example, PbSe, PbTe, PbSnSe, PbSnTe, and/or related alloys. Semiconductor elements 110 and 120 may comprise any good thermoelectric material such as, for example, Bi₂Te₃, PbTe, PbSe, BiSb, GaSb, Ge, (Bi,Sb)₂(Te,Se,S)₃, YbAl₃, CoSi₁₋ₓBₓ, FeSb₂, MnTe₂, La₃Te₄, Ba₈Ga₁₆Ge₃₀, Ca₅Al₂Sb₆, SrZn₂Sb₂, related alloys, nanostructured variants, and/or other polycrystalline materials capable of expressing varying dopant levels. Semiconductor elements 110, 120 can be grown as single crystals with functionally graded carrier concentrations, thereby producing a grading in the Seebeck coefficient. For example, semiconductor elements 110, 120 can be grown by an optical floating zone system. A floating zone system produces precisely functionally graded ingots and single crystals.

FIG. 4 is a cross-sectional view of system 200 for thermoelectric cooling according to another embodiment of the invention. System 200 comprises a pair of semiconductor elements, each comprising three layers. The first semiconductor element comprises a first layer 112, a second layer 114, and a third layer 116. The second semiconductor element comprises a first layer 122, a second layer 124, and a third layer 126. The first and second semiconductor elements are sandwiched between a cold plate 130 and a hot plate 140. The first semiconductor element may be, for example, a P-type semiconductor element, and the second semiconductor element may be, for example, an N-type semiconductor element. In another example, the first semiconductor element may be an N-type semiconductor element, and the second semiconductor element may be a P-type semiconductor element. Although shown and described as a single pair of semiconductor elements, it is contemplated that two or more pairs of semiconductor elements may be implemented in system 200.

The first and second semiconductor elements have rapidly changing Seebeck coefficients from the hot end (i.e., the end proximate to the hot plate 140) to the cold end (i.e., the end proximate to the cold plate 130). In one embodiment, the Seebeck coefficient increases by orders of magnitudes from the cold end to the hot end. Thin film 150 is positioned between third layer 116 and hot plate 140. Thin film 155 is positioned between third layer 126 and hot plate 140. Thin film 150 has the highest Seebeck coefficient with respect to the first semiconductor element. Thin film 155 has the highest Seebeck coefficient with respect to the second semiconductor element.

In this embodiment, multiple functionally graded materials with different effective mass and band gap values are used together to achieve the requisite variation in Seebeck coefficient, while maintaining high zT. Layers 112, 114 and 116 are three bulk segments of the first semiconductor element in series that are individually functionally graded. Layers 122, 124 and 126 are similarly three bulk segments of the second semiconductor element in series that are individually functionally graded. Thin films 150, 155 are final graded thin films. Although shown and described with respect to three layers in the first and second semiconductor element, it is contemplated that any number of layers may be used to create functionally graded first and second semiconductor layers as described herein.

To obtain high Seebeck coefficients at high temperatures, low carrier concentrations are needed along with higher band gaps to suppress minority carrier activation. Third layers 116, 126 may be, for example, thin films with extremely low lattice thermal conductivity (<0.5 Wm⁻¹K⁻¹) and high Seebeck coefficient (>500 μVK⁻¹), which are grown on active thermoelectric single crystals. Third layers 116, 126 may comprise, for example, GaSb, GaAs, Ge, alloys and/or superlattices thereof.

Second layers 114, 124 may be, for example, traditional thermoelectric materials with moderate thermopower (50-500 μVK⁻¹). Second layers 114, 124 may comprise, for example, Bi₂Te₃, PbTe, PbSe, BiSb, (Bi,Sb)₂(Te,Se,S)₃, YbAl₃, CoSi₁₋ₓBₓ, FeSb₂, MnTe₂, PbSnSe, PbSnTe, and/or alloys thereof (such as Bi₉₀Sb₁₀).

First layers 112, 122 may be, for example, low Seebeck coefficient (<50 μVK⁻¹) metals. Thin films 150, 155 may comprise, for example, PbSe, PbTe, PbSnSe, PbSnTe, and/or related alloys. Layers 112, 114, 116, 122, 124 and 126 can be grown using an optical floating zone system, for example. A floating zone system produces precisely functionally graded ingots and single crystals.

In one embodiment, for each temperature range, the optimum material has a low lattice thermal conductivity and high charge carrier mobility. In another embodiment, to achieve the requisite change in Seebeck coefficient and high zT, the effective mass and carrier concentration across the stack may vary from 0.1 to 10 m, and 10¹² to 10²² cm⁻³, respectively.

In this embodiment, low electrical contact resistance exists between the interfaces of layers 112, 114 and 116, as well as between the interfaces of layers 122, 124 and 126. In one embodiment, electrical interconnects are provided between adjacent layers, and metallic diffusion bonds can be used to mechanically and electrically couple the layers together. In some embodiments, these contacting layers act as diffusion barriers to prevent reactions between layers. Low electrical contact resistance also exists at the interface of layer 116 and thin film 150, as well as at the interface of layer 126 and thin film 150. This can be achieved by thin film methods on active bulk substrates.

The semiconductor elements of systems 100, 200 are functionally graded to maintain u=s across each semiconductor element. Three approaches can be used to functionally grade bulk materials: compacted graded powders, directional solidification, and diffusion doping. A single approach can be used to create each semiconductor element, or different techniques can be used for each layer of the semiconductor element.

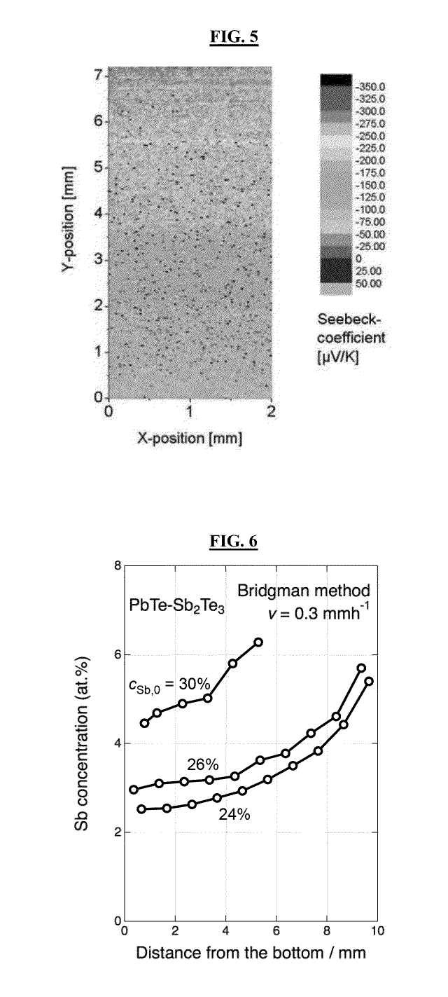

In one embodiment, graded powders are compacted (hot pressed), yielding graded ingots. An example of such an approach is illustrated with respect to Bi₂Te₃ in FIG. 5, which is a scanning Seebeck micrograph of Bi₂Te₃ with varying Seebeck coefficient, prepared via powder processing. In this case, the change in carrier concentration was done through discrete layers. In performing this approach, excessive dopant diffusion during consolidation at high temperature was avoided to avoid destruction of the initial gradient. In one embodiment, inductive heating can be used to enable the sharpest possible interfaces because of the limited time of dopant or alloy diffusion. This embodiment enables the rapid densification of PbTe at 350° C. in 5 minutes, compared to the typical 500° C., multi-hour growths typically employed.

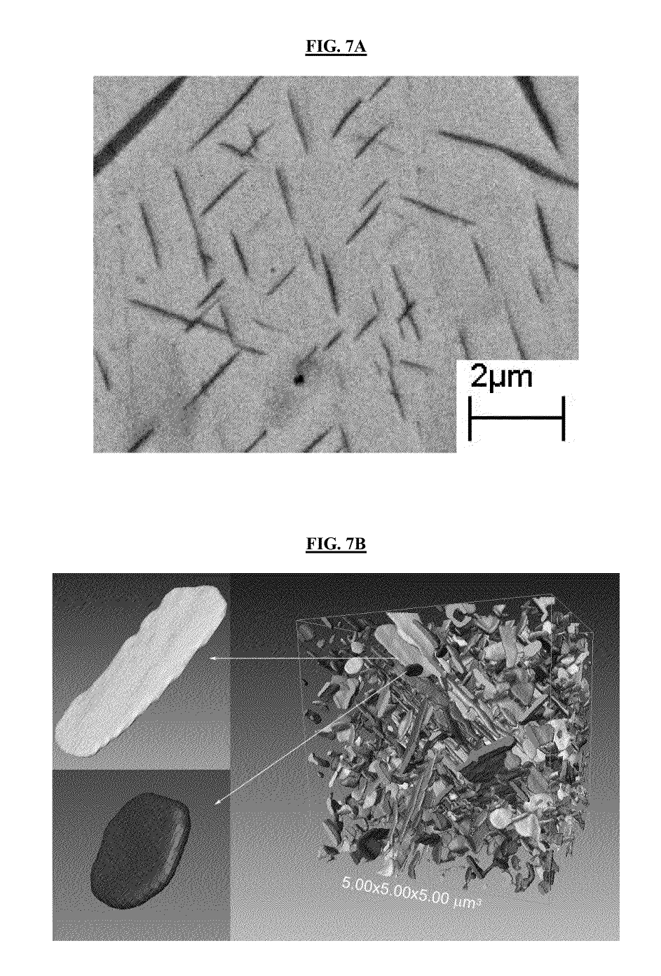

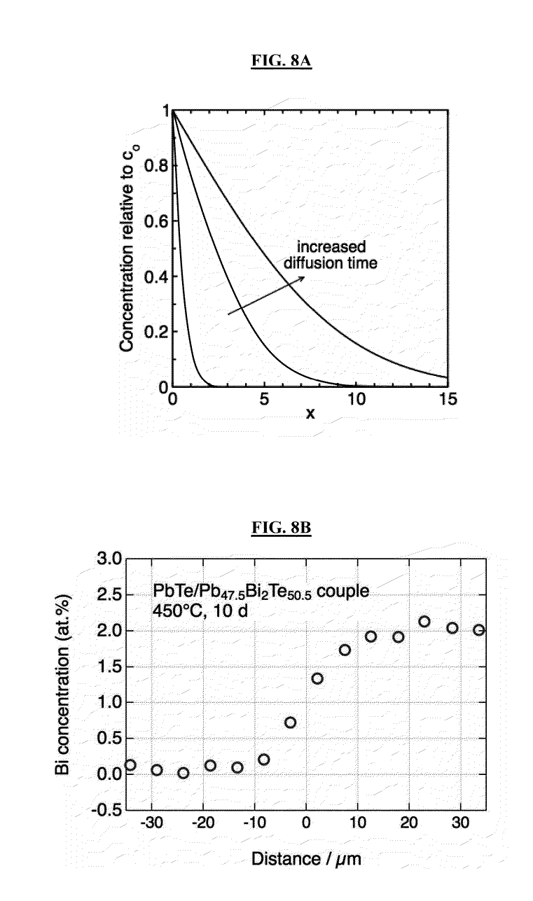

In another embodiment, graded structures are created through controlled solidification and formation of diffusion couples. This embodiment uses the temperature dependence of dopant solubility to form graded thermoelectric materials. FIG. 6 shows an example of PbTe with a graded concentration of Sb in the PbTe using directional solidification. Directionally solidified PbTe—Sb₂Te₃ can control the Sb dopant level in PbTe through control of the processing temperature. Beyond “simple” grading, these structures can include oriented inclusions for phonon scattering to reduce the lattice thermal conductivity. The concentration of the inclusions can be rationally designed from the high temperature phase diagrams. FIGS. 7A and 7B show the crystallographically oriented plates of Sb₂Te₃ in a matrix of single crystalline PbTe. FIG. 7A shows the coherent (epitaxy like) precipitates of Sb₂Te₃ in single crystal PbTe formed by directional solidification. FIG. 7B is a 3D reconstruction of these oriented inclusions.

In still another embodiment, carrier concentration gradients can be created through diffusion doping of ingots from one side, leading to a decay in carrier concentration from the surface. Considering Fick's law in one dimension, the following concentration profile is expected:

$$c ( x ) = {c}_{0} - {c}_{0} erf ( \frac{x}{L} ) \qquad [ 14 ]$$

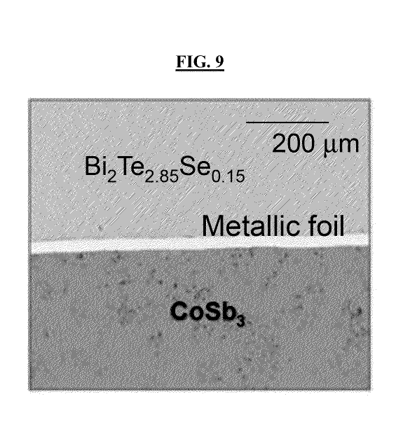

This is shown graphically in FIG. 8A for different diffusion times. As shown in FIG. 8A, diffusion doping leads to a decaying dopant concentration away from the surface. Diffusion doping can occur, for example, through thin film processing of a dopant on one surface followed by controlled annealing to produce dopant gradients. FIG. 8B illustrates a micrometer scale compositional gradient produced by diffusion doping.

A variety of routes to form graded materials is important for a Thomson cooler due to the hierarchy of length scales required in the Seebeck coefficient grading. On the metallic, low temperature side (e.g., on layers 112, 122), macroscopic grading on the order of millimeters is used. In one embodiment, such structures are formed using powder processing. In the middle temperature region (e.g., the region corresponding to layers 114, 124), the relevant length scale is 0.1-1 mm in one embodiment. In this embodiment, these structures are formed by directional solidification. On the high temperature side (e.g., the side comprising layers 116, 126), grading on the order of micrometers is required in one embodiment. These functionally graded materials are optimal for diffusion doping and thin film growth techniques, and can be, for example, thin film super-lattice structures.

As described above, an optical floating zone system may be used to produce precisely functionally graded ingots and single crystals. Such a system enables the synthesis of extremely high quality single crystals for the thermoelectric elements. Floating zone techniques, which grow single crystals in a container-less fashion, avoid secondary nucleation, residual stresses, and the contamination issues associated with other growth methods.

In one embodiment, diffusion bonding of the functionally graded materials to metallization components, other functionally graded materials and diffusion barriers can be achieved via rapid, high temperature, pressure-assisted press for polycrystalline materials. An example cross-sectional interface is shown in FIG. 9. FIG. 9 illustrates two exemplary materials segmented together with metal interconnect by powder processing and diffusion bonding. Thin film processing methods can be used for preparing interfaces, diffusion barriers, and metallization to bulk crystals and thin films.

In an embodiment using lead chalcogenide thin films, molecular beam epitaxy (MBE) can be employed as the growth technique. MBE is favorable because alloys can be formed one atomic layer at a time in the process of epitaxial growth. MBE allows sharp interfaces to be formed between one type of alloy and the next, thus creating structures which can confine electrons and exhibit 2-dimensional behavior. This provides a method of growing high quality bulk material, and of introducing dopants into materials at precisely controlled levels, yielding functionally graded materials. Design features such as alloy composition, layer thickness, and carrier concentration can be controlled by MBE growth flux and shutter open time.

Contact resistance adds additional resistance in series to a thermoelectric leg. Total contact resistance less than 5% of the total resistance of the thermoelectric leg does not significantly affect the performance of the device and is therefore a good target for the interconnects. In a typical bulk thermoelectric device, the thermoelectric materials are approximately 1-2 mm long and have a resistivity of 1 mΩcm². In one embodiment, systems 100, 200 have the geometry and total resistance closer to that of a bulk thermoelectric device than a thin film thermoelectric device; therefore, the contact resistance is about 10⁻⁵ Ωcm². Thus, the necessary contact resistance is orders of magnitude less stringent for a thin film Thomson cooler than a thin film Peltier cooler.

In one embodiment, systems 100, 200 are designed for performance with sensor arrays (such as infrared focal plane arrays), and cool to 140 K with a device ZT of 5. In such an embodiment, the sensor array (or other element to be cooled) is provided over cold plate 130 of FIGS. 3 and 4.

Systems 100, 200 can be operated under pulse operation, for example. In one embodiment, lower temperatures can be achieved using pulse operation as opposed to steady-state operation. Because cooling occurs at a different location than the Joule heating, additional cooling can be achieved for a limited time.

For any application, finding the optimum efficiency and length (l) for any operating condition gives the following functions:

$$\begin{matrix}η = {η}_{ma x} ( {T}_{h} , {T}_{c} ) & [ 15 ] \\ l = l ( \frac{{T}_{h} , {T}_{c} , {Q}_{total}}{{A}_{total}} ) & [ 16 ]\end{matrix}$$

Equations 15 and 16 can be incorporated into the system model to find the optimal system operation condition. The cooling power per area can be altered by adjusting the length of the thermoelectric legs at the cost of increasing the size of the heat exchangers. Given the total voltage desired, the size and number of thermoelectric leg couples can be established.

In another embodiment, cascading provides a mechanism to achieve thermoelectric compatibility. In a cascaded system, there are, in principle, independent electrical circuits for each stage, allowing independent values of u. In this way, different, optimal values of u can be used for each stage.

In such an embodiment, the low temperature stages can be connected directly to the load. However, such connectors would be inefficient because if they had low electrical resistance, they would conduct heat away from the hot side due to Widemann Franz law; however, if they have high electrical resistance, there would be additional Joule losses. To avoid such losses, a further embodiment is provided in which electrical current passes from the low temperature stage to the load by going through the thermoelectric legs of the high temperature stage.

The differing values of u are provided by having a different number of couples in each stage. The ratio of the number of couples (N₂/N₁) in the cooler stage (i.e., Stage 2, N₂ couples) to that of the hotter stage (i.e., Stage 1, N₁ couples), is referred to herein as the cascading ratio. The cascading ratio can be analytically derived using the thermoelectric potential:

$$φ = α T + \frac{1}{u} \qquad [ 17 ]$$

For maximum efficiency, u will be maintained approximately equal to s, within a factor of two. Equating the heat from N₁ stage 1 couples with N₂ stage 2 couples operating with the same electrical current I, gives:

$$\frac{{N}_{2}}{{N}_{1}} = \frac{{φ}_{1}}{{φ}_{2}} \approx \frac{{α}_{1 , p} T + \frac{1}{{s}_{1 , p}} - {α}_{1 , n} T - \frac{1}{{s}_{1 , n}}}{{α}_{2 , p} T + \frac{1}{{s}_{2 , p}} - {α}_{2 , n} T - \frac{1}{{s}_{2 , n}}} \qquad [ 18 ]$$

Other implementations of the invention will be apparent to those skilled in the art from consideration of the specification and practice of the invention disclosed herein. Various aspects and/or components of the described embodiments may be used singly or in any combination. It is intended that the specification and examples be considered as exemplary only, with a true scope and spirit of the invention being indicated by the following claims.

What is claimed is:

1. A system for thermoelectric cooling, the system comprising:
a pair of semiconductor elements, said pair of semiconductor elements comprising a P-type semiconductor element having a first carrier concentration and an N-type semiconductor element having a second carrier concentration, each semiconductor element having a cold end and a hot end;
a cold plate thermally coupled to the cold ends of said P-type semiconductor element and said N-type semiconductor element; and
a hot plate thermally coupled to the hot ends of said P-type semiconductor element and said N-type semiconductor element,
wherein said first carrier concentration is functionally graded over said P-type semiconductor element and said second carrier concentration is functionally graded over said N-type semiconductor element.

2. The system of claim 1, wherein said first carrier concentration increases from said hot end of said P-type semiconductor element to said cold end of said P-type semiconductor element, and
wherein said second carrier concentration increases from said hot end of said N-type semiconductor element to said cold end of said N-type semiconductor element.

3. The system of claim 1, wherein a Seebeck coefficient of said P-type semiconductor element increases from said cold end of said P-type semiconductor element to said hot end of said P-type semiconductor element, and
wherein a Seebeck coefficient of said N-type semiconductor element increases from said cold end of said N-type semiconductor element to said hot end of said N-type semiconductor element.

4. The system of claim 1, wherein said P-type semiconductor element comprises a first plurality of materials, each material being functionally graded, and
wherein said N-type semiconductor element comprises a second plurality of materials, each material being functionally graded.

5. The system of claim 1, wherein said P-type semiconductor element and said N-type semiconductor element each comprise a first section at the cold end, a second section between the cold end and the hot end, and a third section at the hot end.

6. The system of claim 5, wherein said first sections have a Seebeck coefficient less than 50 μVK⁻¹,
wherein said second sections have a Seebeck coefficient of 50 μVK⁻¹ or higher and 500 μVK⁻¹ or lower, and
wherein said third sections have a Seebeck coefficient greater than 500 μVK⁻¹.

7. The system of claim 6, wherein at least one of said third sections is a thin film superlattice.

8. The system of claim 7, wherein said thin film superlattice has a lattice thermal conductivity less than 0.5 Wm⁻¹K⁻¹.

9. The system of claim 6, wherein at least one of said first sections comprises a metal.

10. The system of claim 6, wherein at least one of said third sections comprises at least one of GaSb, GaAs, Ge and alloys thereof.

11. The system of claim 6, wherein at least one of said second sections comprises at least one of PbSe, PbTe, Bi₂Te₃, BiSb, YbAl₃, CoSi₁₋ₓBₓ, FeSb₂, MnTe₂, PbSnSe, PbSnTe, and alloys thereof.

12. The system of claim 11, wherein at least one of said second sections comprises Bi₉₀Sb₁₀.

13. The system of claim 1, wherein a temperature of said cold plate is 140 K or less.

14. The system of claim 1, wherein the pair of semiconductor elements have a figure of merit of 5 or greater.

15. The system of claim 1, wherein the cold plate is thermally coupled to a sensor array.

16. The system of claim 15, wherein the sensor array is an infrared focal plane array.

17. The system of claim 1, wherein the pair of semiconductor elements have a thermoelectric compatibility factor and a reduced current density, and
wherein the thermoelectric compatibility factor and the reduced current density are maintained approximately equal within a factor of two.

18. The system of claim 1, further comprising:
a first thin film coupled between the hot end of the P-type semiconductor element and the hot plate, and
a second thin film coupled between the hot end of the N-type semiconductor element and the hot plate.

19. The system of claim 1, wherein at least one of said P-type semiconductor element and said N-type semiconductor element comprise a single material.

20. The system of claim 1, further comprising:
a first active thermoelectric layer coupled between the hot end of the P-type semiconductor element and the hot plate, and
a second active thermoelectric layer coupled between the hot end of the N-type semiconductor element and the hot plate.
